(19) United States
(12) Patent Application Publication
(10) Pub. No.: US 2025/0351468 A1
(43) Pub. Date: Nov. 13, 2025

(54) Method for Contacting the Gates of a Spin Qubit Gate Array

(71) Applicant: IMEC VZW, Leuven (BE)

(72) Inventors: Boon Teik Chan, Wilsele (BE); Danny Wan, Leuven (BE); Stefan Kubicek, Pellenberg (BE)

(21) Appl. No.: 19/191,571

(22) Filed: Apr. 28, 2025

(30) Foreign Application Priority Data
May 8, 2024 (EP) 24174875.5

(51) Int. Cl. H10D 48/00; H01L 21/768; H01L 23/522; H10D 64/27

(52) U.S. Cl. CPC H10D 48/3835; H01L 21/76802; H01L 21/7684; H01L 21/76877; H01L 23/5226; H10D 64/27

(57) ABSTRACT

An array of gate structures is produced on a planar surface, the array being suitable for the production of a spin qubit quantum dot device. The gate structures include alternately arranged structures of a first and second type. According to the example embodiments, electrical connections to the gate structures of the first and second type are produced in separate process step sequences. The connections to the first gate type include the formation of first conductive lines running essentially parallel to the planar surface and connected to the gate structures of the first type by first via connections. Before producing similar connections to the gate structures of the second type, a conformal dielectric layer is formed on the first conductive lines. The conformal layer is configured so that it forms a protective spacer on the sidewalls of the first conductive lines during processing of the second conductive lines, to avoid shorting.

### CROSS-REFERENCE TO RELATED APPLICATIONS

The present application is a non-provisional patent application claiming priority to European Patent Application No: EP 24174875.5, filed on May 8, 2024, the contents of which are hereby incorporated by reference.

### FIELD OF THE DISCLOSURE

The present disclosure is related to semiconductor spin qubit quantum dot devices comprising an array of gate structures, and in particular to methods for producing electrically conductive contacts to the gate structures.

### BACKGROUND

Quantum dot devices on semiconductor material have been explored extensively in recent years, as one of the main avenues towards realizing a workable quantum computing chip. Various architectures have been explored, which all have in common the presence of closely spaced gates configured so that quantum dots can be confined underneath one or more of these gates. The gates may for example be metal gates formed on a thin layer of silicon oxide lying on a silicon substrate. By the close spacing of the gates and by applying appropriate voltages to the gates, it is possible to create quantum dots underneath the gates, i.e. small isolated electron or hole islands, and to manipulate qubits associated with the quantum dots. The qubits may for example be defined by the spin state of individual electrons of the quantum dots. Magnetic resonance is used to control the spin states, and a read-out device, for example a single electron transistor, may be integrated in the vicinity of the quantum dot or dots. The quantum dot device is operated at a temperature of Kelvin or sub-Kelvin range (i.e. about 1K or less) in order to enable sufficient qubit coherence times and qubit-based computations.

Due to the small spaces between adjacent gates in the device, contacting the gates by electrically conductive structures is challenging. Traditional damascene-type methods for producing conductive vias and lines are subject to overlay errors having the same order of magnitude as the gate interspacing, leading to unacceptable misalignment errors and risk of shorting.

### SUMMARY

The present disclosure is related to a method and a device as disclosed in the appended claims. Throughout this description, the term ‘conductive’ refers to ‘electrically conductive’. An array of gate structures is produced on a planar surface, the array being suitable for the production of a spin qubit quantum dot device. The gate structures include alternately arranged structures of a first and second type, such as plunger gates and barrier gates. According to the example embodiments, electrical connections to the gate structures of the first and second type are produced in separate process step sequences. The connections to the first gate type include the formation of first conductive lines running essentially parallel to the planar surface and connected to the gate structures of the first type by first via connections. Before producing similar connections to the gate structures of the second type, a conformal dielectric layer is formed on the first conductive lines, i.e. on a top surface and on sidewalls of the first conductive lines. The conformal layer is configured, for example in terms of its material and thickness, so that it forms a protective spacer on the sidewalls of the first conductive lines during processing of the second conductive lines, so that shorting between the conductive lines is avoided.

The present example embodiments are in particular related to a method for producing electrical connections to a plurality of adjacent gate structures of a spin qubit gate array, the method comprising the steps of:
producing the gate structures on a planar substrate surface by producing a hardmask layer on a gate layer, patterning the hardmask layer and transferring the patterned hardmask layer to the gate layer, thereby obtaining the adjacent gate structures, with a hardmask portion on each gate structure, wherein the gate structures comprise alternately arranged structures of a first and second type arranged in a longitudinal direction,
producing first via connections connected to the gate structures of the first type and mutually parallel first conductive lines connected respectively to the first via connections, the first conductive lines running essentially parallel to the planar substrate surface,
thereafter, producing a conformal dielectric layer on the sidewalls and the top surface of the first conductive lines, the first conductive lines having sidewalls and a top surface. The term ‘conformal layer’ is defined as a layer that follows the topography of the surface onto which it is deposited. Implicitly, this means that the layer's thickness is suitable for this purpose, i.e. the layer is thin compared to the dimensions of the features defining the topology.
thereafter, producing second via connections connected to the gate structures of the second type and mutually parallel second conductive lines connected respectively to the second via connections, the second conductive lines running essentially parallel to the planar substrate surface,
wherein the conformal layer forms spacers on the sidewalls of the first conductive lines, the spacers remaining on the sidewalls during the formation of the second conductive lines, so that the conformal layer enables isolating the first conductive lines from the second conductive lines regardless of possible alignment errors between on the one hand the gate structures of the first and second type and on the other hand the respective first and second conductive lines.

According to an embodiment: the first via connections and the first conductive lines are produced by:
embedding the gate structures and the hardmask portions in a first dielectric layer,
planarizing the first dielectric layer,
producing first trenches in the first dielectric layer, the first trenches respectively overlapping the gate structures of the first type, so that at least a part of the hardmask portions on the gate structures of the first type is exposed at the bottom of the first trenches,
removing at least part of the material of the respective hardmask portions exposed at the bottom of the first trenches, to thereby create first via openings which expose the gate structures of the first type,
filling the first via openings and the first trenches with a conductive material, to thereby obtain the first via connections,
planarizing the conductive material and the first dielectric layer to thereby obtain the first conductive lines embedded in the planarized first dielectric layer,
thereafter, the first dielectric layer is recessed until the first conductive lines are lying on top of a recessed surface of the first dielectric layer, the first conductive lines having sidewalls and a top surface,
the conformal dielectric layer is produced on the recessed surface and on the sidewalls and the top surface of the first conductive lines,
thereafter, second via connections are produced, connected to the gate structures of the second type and mutually parallel second conductive lines are produced, connected respectively to the second via connections, the second conductive lines running essentially parallel to the planar substrate surface, wherein the second via connections and the second conductive lines are produced by:
embedding the first conductive lines including the conformal layer in a second dielectric layer,
planarizing the second dielectric layer,
producing second trenches in the second dielectric layer, the second trenches respectively overlapping the gate structures of the second type, by removing material of the second dielectric layer using an etch recipe that is selective with respect to the material of the conformal layer,
removing the material of the conformal layer from the bottom of the second trenches, while maintaining the conformal layer on the sidewalls of the first conductive lines, thereby forming deepened second trenches, wherein at least a part of the hardmask portions on the gate structures of the second type is exposed at the bottom of the deepened second trenches,
removing at least part of the material of the respective hardmask portions exposed at the bottom of the deepened second trenches, thereby creating second via openings which expose the gate structures of the second type,
filling the second via openings and the deepened second trenches with an electrically conductive material, to thereby obtain the second via connections,
planarizing the electrically conductive material and the second dielectric layer to thereby obtain the second conductive lines embedded in the planarized second dielectric layer.

According to an embodiment, the gate layer is a single layer of gate material so that the mask portions are formed directly on respective gate structures formed uniformly of the gate material.

According to an embodiment, the gate layer comprises a bottom layer formed of a first gate material and a top layer directly on the bottom layer and formed of a second gate material, so that the mask portions are formed directly on respective gate structures formed of a stack of a bottom gate portion of the first gate material and a top gate portion of the second gate material on top of the first gate portion, and:
the formation of the first via openings includes the removal of at least part of the top gate portions of the gate structures of the first type relative to the bottom gate portions,
the formation of the second via openings includes the removal of at least part of the hardmask portion) on the gate structures of the second type without removing the top gate portions of the gate structures of the second type.

According to an embodiment, the lateral dimensions of the gate structures and the spacing between adjacent gate structures are between 5 and 50 nm and the thickness of the conformal layer is between 1 and 5 nm.

According to an embodiment, the material of the hardmask portions is silicon nitride, and the conformal layer comprises at least a top layer formed of silicon carbonate.

According to an embodiment, the second gate material is a metal.

The present example embodiments are equally related to a spin qubit quantum dot device comprising:
an array of alternately arranged gate structures of a first and second type arranged in a longitudinal direction on a planar surface,
first via connections to the gate structures of the first type, the first via connections being connected to respective first conductive lines running essentially parallel to the planar surface,
second via connections to the gate structures of the second type, the second via connections being connected to respective second conductive lines running essentially parallel to the planar surface,
wherein the first and the second conductive lines are embedded in a layer of dielectric material, the layer comprising spacers on the sidewalls of the first conductive lines.

According to an embodiment of the device, the lateral dimensions of the gate structures and the spacing between adjacent gate structures are between 5 and 50 nm and the thickness of the spacers is between 1 and 5 nm.

### BRIEF DESCRIPTION OF THE FIGURES

The above, as well as additional, features will be better understood through the following illustrative and non-limiting detailed description of example embodiments, with reference to the appended drawings.

FIG. 1 illustrates a schematic representation of an array of structures applicable for the production of a quantum dot device, according to an example embodiment.

FIG. 2 illustrates a section view along line A-A′, according to an example embodiment.

FIG. 3 illustrates an array covered by a layer of dielectric material, according to an example embodiment.

FIG. 4 illustrates the deposition and patterning of a hardmask layer on the planarized interlayer dielectric, according to an example embodiment.

FIG. 5a illustrates the pattern with two trenches with a view along the X direction, according to an example embodiment.

FIG. 5b illustrates the pattern with two trenches with a view along the Y direction, according to an example embodiment.

FIG. 6 illustrates the trench pattern of the hardmask transferring by anisotropic etching, according to an example embodiment.

FIG. 7a illustrates a section view oriented along the X direction showing the via openings above the plunger gates, according to an example embodiment.

FIG. 7b illustrates a section view oriented along the Y direction showing the via openings above the plunger gates, according to an example embodiment.

FIG. 8 illustrates the trenches and via openings filled with an electrically conductive material, according to an example embodiment.

FIG. 9a illustrates the planarized metal with a view along the X direction, according to an example embodiment.

FIG. 9b illustrates the planarized metal with a view along the Y direction, according to an example embodiment.

FIG. 10 illustrates the ILD material recessed by etching, according to an example embodiment.

FIG. 11 illustrates a deposited conformal dielectric layer, according to an example embodiment.

FIG. 12 illustrates the depositing of further ILD material and planarizing the material, according to an example embodiment.

FIG. 13 illustrates the formation of a further patterned hardmask on the planarized surface, according to an example embodiment.

FIG. 14 illustrates the hardmask being transferred to the underlying ILD layer, according to an example embodiment.

FIG. 15 illustrates the result of the application of an etch recipe, according to an example embodiment.

FIG. 16a illustrates the creation of via openings, with a view along the X direction, according to an example embodiment.

FIG. 16b illustrates the creation of via openings, with a view along the Y direction, according to an example embodiment.

FIG. 17 illustrates the via openings filled with a metal, according to an example embodiment.

FIG. 18 illustrates conductive lines with high risk of shorting without a conformal layer, according to an example embodiment.

FIG. 19 illustrates a step in the method with the trench masks perfectly aligned respective to the widths of the plunger gates and barrier gates according to an example embodiment.

FIG. 20 illustrates a step in the method with the trench masks perfectly aligned respective to the widths of the plunger gates and barrier gates according to an example embodiment.

FIG. 21 illustrates a step in the method with the trench masks perfectly aligned respective to the widths of the plunger gates and barrier gates according to an example embodiment.

FIG. 22 illustrates a step in the method with the trench masks perfectly aligned respective to the widths of the plunger gates and barrier gates according to an example embodiment.

FIG. 23 illustrates a step in the method with the trench masks perfectly aligned respective to the widths of the plunger gates and barrier gates according to an example embodiment.

FIG. 24 illustrates a step in the method with the trench masks perfectly aligned respective to the widths of the plunger gates and barrier gates according to an example embodiment.

FIG. 25 illustrates a step in the method with the trench masks perfectly aligned respective to the widths of the plunger gates and barrier gates according to an example embodiment.

FIG. 26 illustrates a step in the method with the trench masks perfectly aligned respective to the widths of the plunger gates and barrier gates according to an example embodiment.

FIG. 27 illustrates a step in the method with the trench masks perfectly aligned respective to the widths of the plunger gates and barrier gates according to an example embodiment.

FIG. 28 illustrates a step in the method with the trench masks perfectly aligned respective to the widths of the plunger gates and barrier gates according to an example embodiment.

FIG. 29 illustrates a step in the method with the trench masks perfectly aligned respective to the widths of the plunger gates and barrier gates according to an example embodiment.

FIG. 30 illustrates the initial structure with two different metals, according to an example embodiment.

FIG. 31 illustrates the first trenches formed above the barrier gates, according to an example embodiment.

FIG. 32 illustrates the hardmask portions and top gate portions of the barrier gate removed at the bottom of the trenches, according to an example embodiment.

FIG. 33 illustrates metal filling and recessing of the ILD material, according to an example embodiment.

FIG. 34 illustrates the structure with the conformal layer deposited, according to an example embodiment.

FIG. 35 illustrates the structure with the formation of a further ILD layer and trenches, according to an example embodiment.

FIG. 36 illustrates the structure where the hardmask portions are anisotropically removed at the bottom of the trenches, according to an example embodiment.

FIG. 37 illustrates the structure, where the second metal fill creates conductive lines and via connections to the top portion of the plunger gate, according to an example embodiment.

All the figures are schematic, not necessarily to scale, and generally only show parts which are necessary to elucidate example embodiments, wherein other parts may be omitted or merely suggested.

### DETAILED DESCRIPTION

Example embodiments will now be described more fully hereinafter with reference to the accompanying drawings. That which is encompassed by the claims may, however, be embodied in many different forms and should not be construed as limited to the embodiments set forth herein; rather, these embodiments are provided by way of example. Furthermore, like numbers refer to the same or similar elements or components throughout.

FIG. 1 is a schematic representation of an array of structures applicable for the production of a quantum dot device. The array is formed on the surface 1 of a substrate of which the details are not shown, but which may be in accordance with known practice, for example a silicon substrate comprising a silicon oxide layer on its surface, so that the structures of the array are formed directly on the silicon oxide layer, with the aim of creating quantum dots at the interface between the silicon and the silicon oxide. The array includes larger structures 2 at the outer ends, which may for example serve as source and drain-type electrodes in the eventual device, and a row of alternately arranged gate structures 3 and 4 of a first and second type. The function of these latter gate structures in the eventual device will be to enable read and write operations to and from the quantum dots and to separate quantum dots from each other. It is known to refer to these respective gate structures as plunger gates and barrier gates, and this terminology will be used in the present detailed description. So in the presented example, the gate structures of the first type are plunger gates 3 and the gate structures of the second type are barrier gates 4. However in the broader scope of the appended claims, the meaning of ‘first and second gate structures’ may be reversed or the first and second type could refer to other gate types besides barrier and plunger gates.

In an example embodiment, a configuration shown in FIG. 1 includes two plunger gates 3 separated by a barrier gate 4 between the two plunger gates, while further barrier gates 4 separate the plunger gates 3 from the laterally placed source and drain-type electrodes 2. This is merely an example embodiment of a configuration, and the number of gate structures can be higher than shown.

The eventual quantum dot device may also include additional gate structures or electrodes besides the ones shown in FIG. 1, such as confinement structures formed of the same material as the gate structures and placed in the vicinity of the gate array. Such additional structures are not shown in the drawing which focuses on the actual array itself. The material of the gates 3,4 and the source and drain-type structures 2 may be any suitable electrically conductive material, such as copper or ruthenium. The present disclosure is not limited to specific dimensions of the various structures, but finds its primary usefulness in relation to very small gate features. For example, the width in the X-direction, as seen with respect to the axis system included in FIG. 1, of the plunger gates 3 may be in the order of 10-15 nm, with the width of the barrier gates 4 being somewhat smaller, for example 5-10 nm, and with interspacings between adjacent gates in the order of 5-10 nm. In the orthogonal Y direction, the dimensions may be somewhat larger, so that the gates have rectangular shapes as illustrated. However, other gate shapes are possible (square, rounded, etc), as is known in the art.

It is seen in FIG. 1 that the plunger and barrier gates 3, 4 and the source and drain-type electrodes 2 are each covered by respective hardmask portions 3′, 4′ and 2′ which may be formed of silicon nitride (Si₃N₄, hereafter abbreviated as ‘SiN’). The hardmask portions have remained after the formation of the gate structures 3, 4 and electrodes 2 by lithography and etching, which includes depositing a hardmask layer on a layer of the gate material, patterning the hardmask layer and transferring the patterned hardmask to the gate layer by etching. Methods for patterning the hardmask and transferring the patterned hardmask features to the gate layer at the small feature sizes described above are known as such and the present disclosure is applicable in combination with any such known methodologies. The present disclosure is in other words applicable to a configuration as shown in FIG. 1, obtained by any method known in the art. The thickness of the gates 3,4, and electrodes 2 and of the hardmask portions 2′,3′,4′ may be in the order of a few nanometers, for example between 10 and 50 nm.

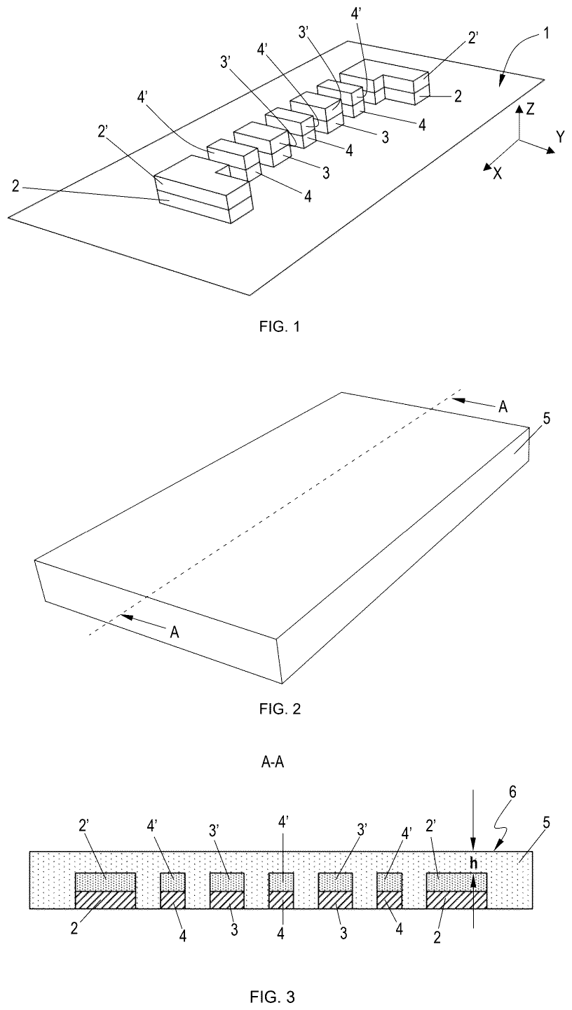

With reference to FIG. 2 and in the section view along line A-A, shown in FIG. 3, the array is first covered by a layer 5 of dielectric material that is subsequently planarized to a planar level extending above and distanced by a distance ‘h’ from the top of the hardmask portions 2′, 3′, 4′, wherein the distance h is between 10 and 50 nm for example. Alternatively, layer 5 is planarized down to the hardmask portions 2′-4′ which are used as planarization stop surfaces, and a further dielectric layer of the same material and of thickness h is deposited on the planarized surface. The material of layer 5 and (if applicable) of the additionally deposited layer of thickness h may be any dielectric material applicable as an interlayer dielectric (ILD) material in back end of line processing (BEOL), such as silicon oxide. Layer 5 as shown in the drawings is therefore one embodiment of the ‘first dielectric layer’ referred to in the following method steps stated in the appended claims:
embedding the gate structures (3,4) and the hardmask portions (3′,4′) in a first dielectric layer (5),
planarizing the first dielectric layer (5),

Based on the above clarifications, it is clear that the ‘first dielectric layer’ can be a uniform layer formed by one single deposition and then planarized, as well as a layer comprising a first layer that is planarized to the level of the hardmask portions 3′, 4′ and a second planarized layer formed thereon. Also, the step of planarizing the layer is such that the planarized surface is distanced (by distance ‘h’) from the upper surface of the hardmask portions 3′, 4′.

Planarization steps referred to throughout this description may include grinding steps for thinning a layer, and more finetuned planarization techniques such as chemical mechanical polishing (CMP), applied according to known parameters and recipes.

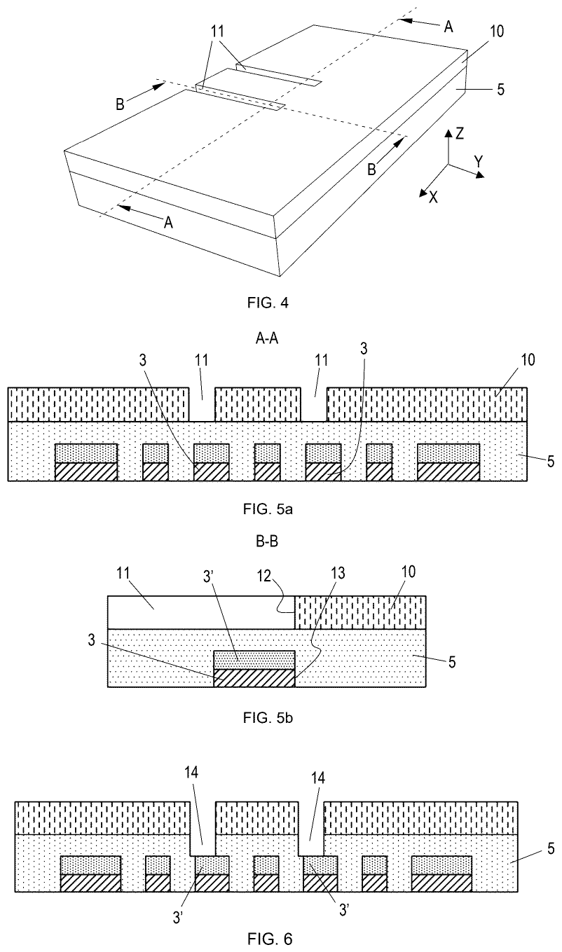

Reference is made to FIG. 4, illustrating the deposition and patterning of a hardmask layer 10 on the planarized ILD surface 6, produced by standard lithography and etching techniques. The hardmask 10 could be formed of SiN or any other suitable material. The pattern comprises two trenches 11 positioned respectively above the plunger gates 3 in the manner illustrated in the section views taken along two orthogonal planes AA and BB oriented in the X and Y directions, as shown respectively in FIGS. 5a and 5b. The width in the X-direction of the trenches 11 is somewhat smaller than the width of the plunger gates 3. Furthermore, the trenches 11 may have the same width as the plunger gates 3 or even a somewhat larger width than the plunger gates, as long as the method steps described hereafter are enabled.

In the Y-direction, the trenches have a closed end face 12 that is aligned to the sides 13 of the plunger gates 3. In the X-direction, the trenches are aligned to the plunger gates. However, it is seen that the alignment of the trenches relative to the width of the plunger gates in the X-direction is not perfect and that a misalignment of a few nanometers has occurred. This misalignment is the consequence of an overlay error during the lithography steps applied for producing the patterned hardmask 10. Such overlay errors may be unavoidable, and a misalignment between 0 and about 5 nm must therefore be taken into account. In other words, the center lines of the trenches 11 could be perfectly aligned to the centerlines of the plunger gates 3, or the centerlines could be shifted relative to each other when there is a misalignment. The example embodiments are configured to enable correctly contacting the plunger and barrier gates 3,4 even when a clearly measurable misalignment has occurred, as in the case illustrated. The way in which this is done will be described in the following paragraphs.

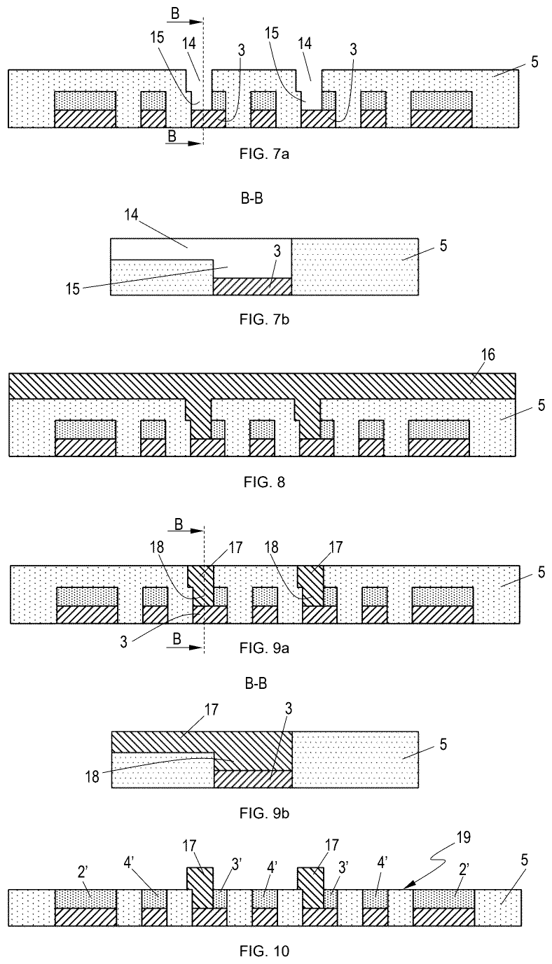

With reference to FIGS. 6 and 7, the trench pattern of the hardmask 10 is transferred by anisotropic etching to the ILD layer 5, i.e. trenches 14 are formed in the ILD layer 5. The hardmask portions 3′ are partly exposed at the bottom of these trenches 14. After stripping the hardmask 10, material of the hardmask portions 3′ is removed anisotropically, thereby creating via openings 15 above the plunger gates 3, as visualized in the section views taken again along planes oriented respectively in the X and Y directions in FIGS. 7a and 7b.

The trenches 14 and via openings 15 are then filled with an electrically conductive material 16, such as a metal, as illustrated in FIG. 8. The metal deposition may possibly be preceded by depositing a seed layer and/or a barrier layer (not shown). The metal 16 is planarized as illustrated in FIGS. 9a and 9b, thereby creating metal lines 17 running essentially parallel to the substrate surface 1, and connected to the plunger gates 3 by via connections 18.

With reference to FIG. 10, the ILD material of layer 5 is then recessed by etching the material back relative to the conductive lines 17, until the lines extend upward from the recessed surface 19. The recessing etchback process stops on the upper surface of the hardmask portions 2′, 3′, 4′.

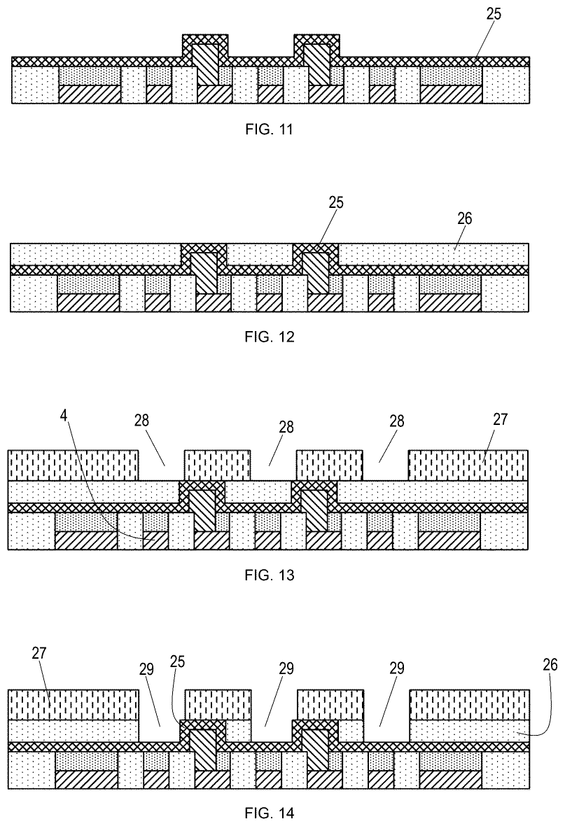

Then a conformal dielectric layer 25 is deposited, as illustrated in FIG. 11. The term ‘conformal’ within the present context is defined as a layer that follows the topography of the surface onto which it is deposited. Implicitly, this means that the layer's thickness is suitable for this purpose, i.e. the layer is thin compared to the dimensions of the features defining the topology, in this case the width and height of the conductive lines 17. The conformal layer thus forms a liner on the sidewalls and upper surfaces of the conductive lines 17 and on the recessed ILD surface 19. The thickness of the conformal layer 25 is for example between 1 and 5 nanometer in the case of the gate dimensions referred to above. The material of the conformal layer 25 is chosen with respect to its functionality as described hereafter, and may for example be silicon carbooxide (hereafter abbreviated as SiCO) or silicon oxycarbonitride (hereafter abbreviated as SiOCN). The conformal layer 25 could also comprise multiple sublayers. For example layer 25 could be a stack of a layer of SiN with a layer of SiCO thereon, or a stack of a layer of SiON (Silicon oxynitride) with a layer of SiOCN thereon. Deposition of these types of layer 25 can be done by known techniques, for example applied in process flows which require similar conformal layer depositions on nano-sized features, such as self-aligned double or multiple patterning methods.

The deposition of the conformal layer 25 is followed by depositing further ILD material 26, and planarizing the material as illustrated in FIG. 12, followed by the formation of a further patterned hardmask 27 on the planarized surface, as illustrated in FIG. 13. The pattern again comprises trench shapes 28, which are now aligned to the barrier gates 4. The width of the trenches 28 may be somewhat larger than the width of the respective barrier gates 4 as shown in the drawings, but the trenches 28 could have the same or smaller width compared to the barrier gates 4. Again, a degree of misalignment in the X-direction has occurred, as illustrated by the fact that the center lines of the trenches 28 are shifted over a few nanometers with respect to the center lines of the barrier gates 4.

With reference to FIG. 14, the hardmask 27 is transferred to the underlying ILD layer 26, i.e. trenches 29 are formed in the ILD material by etching anisotropically at the trench positions. Due to the misalignments, it is seen that the trenches 28 in the hardmask 27 are partly overlapping the conformal layer 25 formed on the sidewalls of the conductive lines 17. The etch process for removing the ILD material is selective with respect to the conformal layer 25 so that the latter is essentially not removed by the etch process.

In the case of the misaligned conductive lines 17, this selectiveness has the effect of a self-aligning function of the conformal layer 25 formed on the sidewalls of the misaligned lines 17 at the right-hand side of the trenches 29 formed in the ILD layer 26, these trenches 29 are effectively aligned to the conformal layers rather than to the trenches 28 defined in the hardmask 27. This self-aligning function will ensure that no shorting occurs between adjacent conductive lines in the eventual device, as described further in this text.

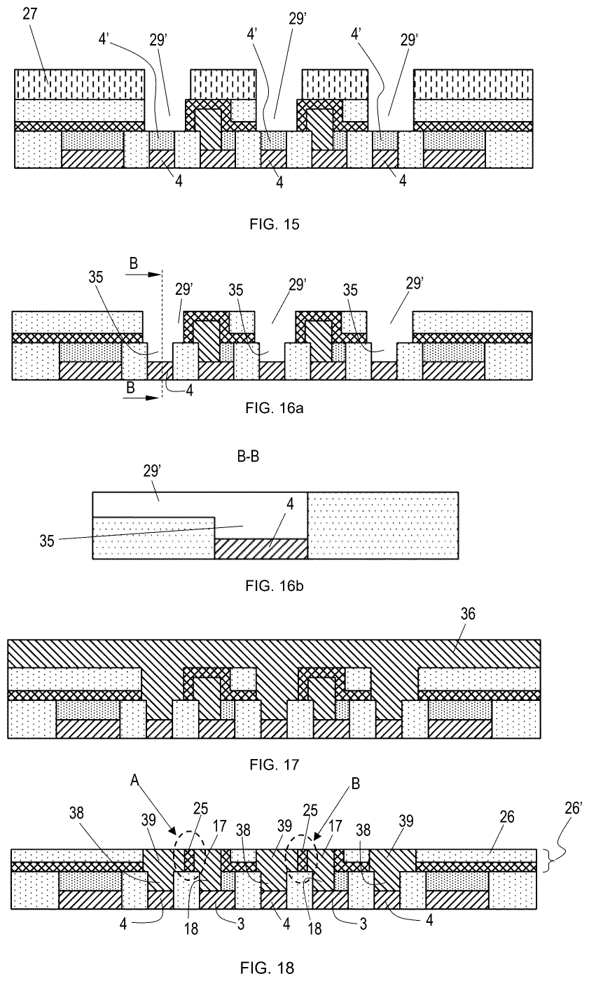

Even though the material of the conformal layer 25 is not removed during etching of the ILD material 26, at the bottom of the trenches 29, the material of the conformal layer 25 needs to be removed, whilst still preserving the conformal layer 25 on the sidewalls of the conductive lines 17. Removal of the conformal layer 25 from the bottom of the trenches 29 is therefore done by a specific etch recipe configured to remove only material from horizontal level surfaces, and not from vertical surfaces. These types of plasma etch recipes are well-known in the art and applied in the above-referenced double or multiple patterning process flows for creating side spacers. The application of this etch recipe leads to the situation shown in FIG. 15: trenches 29′ are formed above the respective barrier gates 4, with the hardmask portions 4′ exposed at the bottom of the trenches 29′. The trenches 29′ are deepened with respect to the trenches 29 and are therefore referred to as ‘deepened trenches’ in the appended claims.

The hardmask portions 4′ are then removed by an etch process that is selective relative to the material of the conformal layer 25. When the hardmask portions 4′ are formed of SiN, this means that the material of the conformal layer 25 can for example be SiCO, or the conformal layer can be a stack of SiN and SiCO.

The removal of the hardmask portions 4′ results in the creation of via openings 35 as illustrated in FIGS. 16a and 16b. The via openings 35 and the trenches 29′ are then filled with a metal 36 (FIG. 17), that is planarized, as illustrated in FIG. 18, creating via connections 38 and conductive lines 39 connected to the barrier gates 4. The planarization removes also the conformal layer 25 on top of the first conductive lines 17, so that a planarized dielectric surface is obtained, with conductive lines embedded therein, including first conductive lines 17 contacting the plunger gates 3 and second conductive lines 39 contacting the barrier gates 4. The lines are isolated from each other by the ILD material of layer 5, and by the material of the conformal layer 25.

It is clear from the preceding description that without the presence of the conformal layer 25, there would be a high risk of shorting between the adjacent conductive lines at locations A and B indicated in FIG. 18. In other words, the conformal layer 25 ensures that the conductive lines 17 and 39 are isolated from each other at these locations, despite the misalignment of the respective trench-shaped hardmasks 10 and 27. This explains the functionality of the conformal layer 25. To obtain this result, the material of the conformal layer 25 needs to be chosen such that the ILD material of layers 5 and 26 and the material of the hardmask portions 3′ and 4′ can be removed selectively with respect to this material.

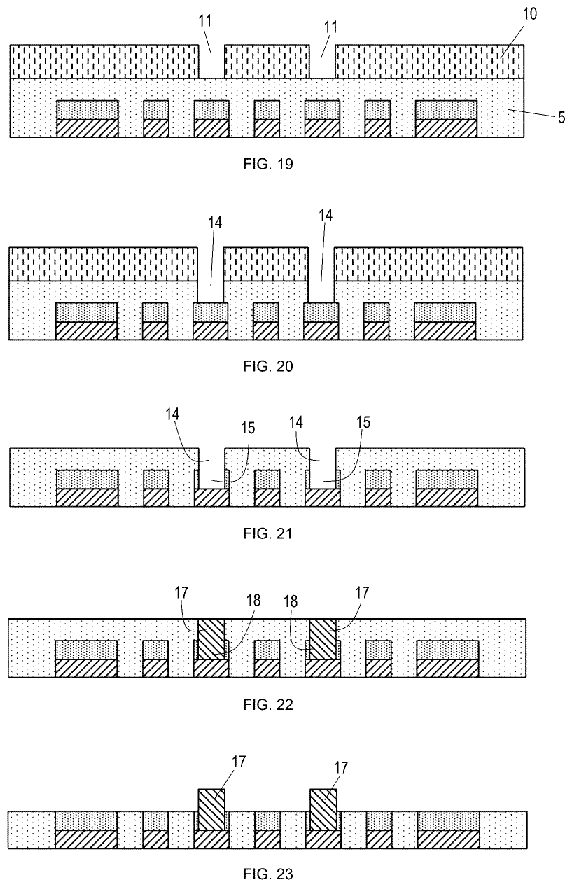

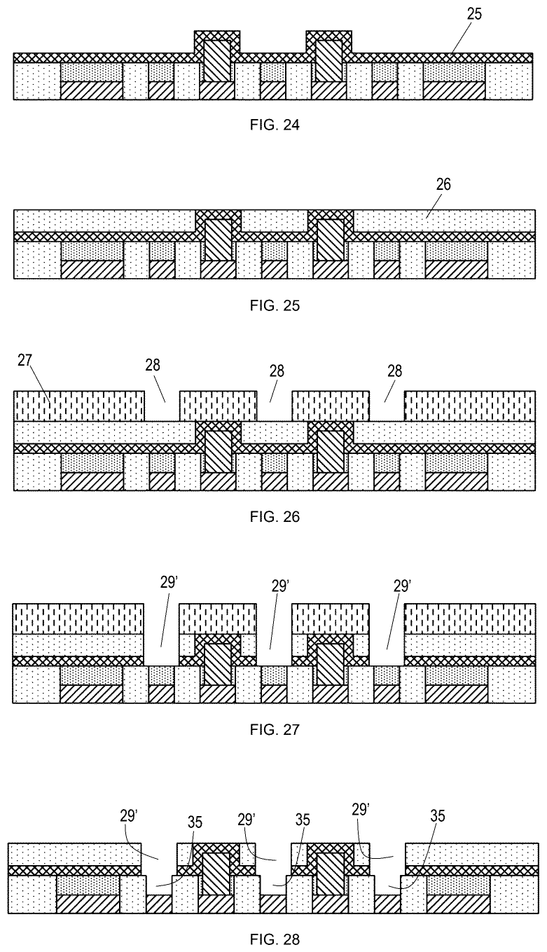

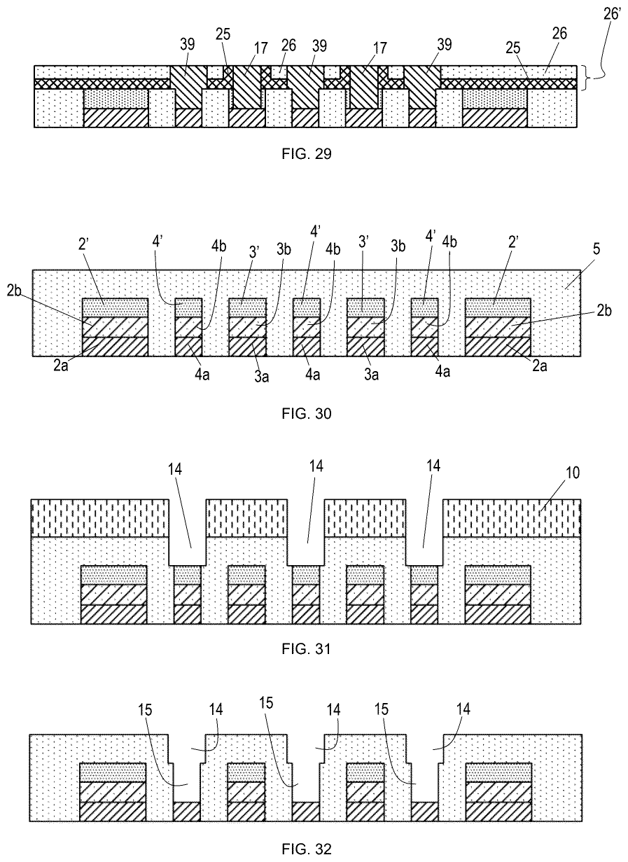

FIGS. 19 to 29 illustrate the same sequence but now with the trench masks 10 and 27 being perfectly aligned respectively to the widths of the plunger gates 3 and the barrier gates 4. In the image in FIG. 29, it is seen that this time, any pair of adjacent conductive lines 17,39 is isolated from each other by ILD material 26 and material of the conformal layer 25. This will be the case also if a very small degree of misalignment occurs. In other words, when the misalignment error is zero or small, the self-aligning function of the conformal layer 25 is not actively applied. However as soon as the misalignment goes beyond a given value, this self-aligning function does come into play as illustrated in FIGS. 1-18, and this avoids eventual shorting between adjacent lines.

A quantum dot device produced according to the example embodiments comprises gate structures 3, 4 of a first and second type with first and second via connections 18,38 and first and second conductive lines 17,39 connected to the respective first and second type gate structures. The device can be recognized by the fact that the first and second conductive lines are embedded in a dielectric layer 26′ (as indicated in FIGS. 18 and 29), the layer comprising spacers on the sidewalls of the first conductive lines 17. The spacers are the portions of the conformal layer 25 remaining on the sidewalls of the first conductive lines 17. In the finished device, the spacers are defined as layers of a dielectric material that is different from the remainder of the dielectric layer 26′ that is embedding the first and second conductive lines. The ‘remainder’ is the material of layer 26 applied in the steps illustrated in FIGS. 12 and 25.

A further embodiment is illustrated in FIGS. 30 to 37. As seen in FIG. 30, the initial structures now comprise two metal portions: the plunger gates 3 comprise a bottom portion 3a and a top portion 3b while the barrier gates 4 comprise a bottom portion 4a and a top portion 4b. The bottom and top portions are formed of different metals, for example W and Ru. In the particular sequence, first trenches 14 are formed above the barrier gates 3, as illustrated in FIG. 31, but these first trenches could instead be formed above the plunger gates as in the previous embodiments. The theoretical case is represented of trenches which are perfectly aligned to the barrier gates 3, but a degree of misalignment is possible, as described above.

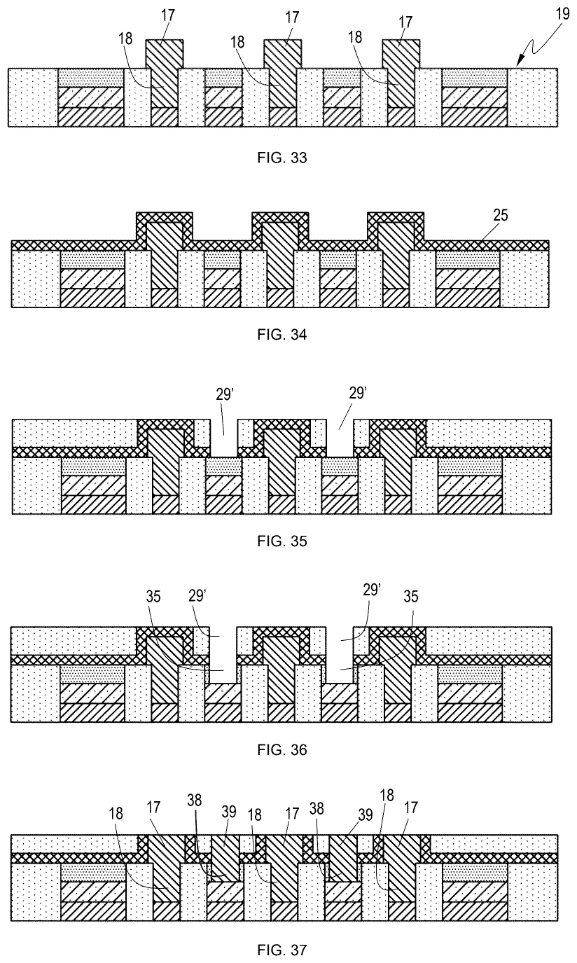

Both the hardmask portions 4′ and the top gate portions 4b of the barrier gates are removed at the bottom of the trenches 14, as represented in FIG. 32, creating via openings 15 towards the remaining bottom barrier gate portions 4a. This is followed by metal filling and recessing of the ILD material, as illustrated in FIG. 33, resulting in first conductive lines 17 lying on top of the recessed ILD surface 19 and connected to the barrier gates by via connections 18. The conformal layer 25 is deposited, as shown in FIG. 34, followed (FIG. 35) by the formation of a further ILD layer and of trenches 29′ formed therein, above the plunger gates 3, and aligned thereto in the case shown, keeping in mind that a degree of misalignment is possible. With reference to FIG. 36, the hardmask portions 3′ are anisotropically removed at the bottom of the trenches 29′, and a second metal fill creates conductive lines 39 and via connections 38 to the top portion 3b of the plunger gates. The two-metal gate structures enable the creation of a level difference between the contacts to the two gate types, which is beneficial in terms of increasing the distance between adjacent gate contacts. In this example embodiment, there is less chance of an electrical short between the gate contacts.

While the present disclosure has been illustrated and described in detail in the drawings and foregoing description, such illustration and description are to be considered illustrative or exemplary and not restrictive. Other variations to the disclosed embodiments can be understood and effected by those skilled in the art, from a study of the drawings, the disclosure and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

While some embodiments have been illustrated and described in detail in the appended drawings and the foregoing description, such illustration and description are to be considered illustrative and not restrictive. Other variations to the disclosed embodiments can be understood and effected in practicing the claims, from a study of the drawings, the disclosure, and the appended claims. The mere fact that certain measures or features are recited in mutually different dependent claims does not indicate that a combination of these measures or features cannot be used. Any reference signs in the claims should not be construed as limiting the scope.

What is claimed is:

1. A method for producing electrical connections to a plurality of adjacent gate structures of a spin qubit gate array, the method comprising the steps of:
producing the gate structures on a planar substrate surface by producing a hardmask layer on a gate layer, patterning the hardmask layer and transferring the patterned hardmask layer to the gate layer, thereby obtaining the adjacent gate structures, with a hardmask portion on each gate structure, wherein the gate structures comprise alternately arranged structures of a first and second type arranged in a longitudinal direction,
producing first via connections connected to the gate structures of the first type and mutually parallel first conductive lines connected respectively to the first via connections, the first conductive lines running essentially parallel to the planar substrate surface,
thereafter, producing a conformal dielectric layer on the sidewalls and the top surface of the first conductive lines, the first conductive lines having sidewalls and a top surface, and
thereafter, producing second via connections connected to the gate structures of the second type and mutually parallel second conductive lines connected respectively to the second via connections, the second conductive lines running essentially parallel to the planar substrate surface,
wherein the conformal layer forms spacers on the sidewalls of the first conductive lines, the spacers remaining on the sidewalls during the formation of the second conductive lines.

2. The method according to claim 1, wherein:
the first via connections and the first conductive lines are produced by:
embedding the gate structures and the hardmask portions in a first dielectric layer,
planarizing the first dielectric layer,
producing first trenches in the first dielectric layer, the first trenches respectively overlapping the gate structures of the first type, so that at least a part of the hardmask portions on the gate structures of the first type is exposed at the bottom of the first trenches,
removing at least part of the material of the respective hardmask portions exposed at the bottom of the first trenches, to thereby create first via openings which expose the gate structures of the first type,
filling the first via openings and the first trenches with a conductive material, to thereby obtain the first via connections, and
planarizing the conductive material and the first dielectric layer to thereby obtain the first conductive lines embedded in the planarized first dielectric layer.

3. The method according to claim 2, wherein, the first dielectric layer is recessed until the first conductive lines are lying on top of a recessed surface of the first dielectric layer, the first conductive lines having sidewalls and a top surface.

4. The method according to claim 3, wherein, the conformal dielectric layer is produced on the recessed surface and on the sidewalls and the top surface of the first conductive lines.

5. The method according to claim 4, wherein second via connections are produced, connected to the gate structures of the second type and mutually parallel second conductive lines are produced, connected respectively to the second via connections, the second conductive lines running essentially parallel to the planar substrate surface.

6. The method according to claim 5, wherein the second via connections and the second conductive lines are produced by:
embedding the first conductive lines including the conformal layer in a second dielectric layer,
planarizing the second dielectric layer,
producing second trenches in the second dielectric layer, the second trenches respectively overlapping the gate structures of the second type, by removing material of the second dielectric layer using an etch recipe that is selective with respect to the material of the conformal layer,
removing the material of the conformal layer from the bottom of the second trenches, while maintaining the conformal layer on the sidewalls of the first conductive lines, thereby forming deepened second trenches, wherein at least a part of the hardmask portions on the gate structures of the second type is exposed at the bottom of the deepened second trenches,
removing at least part of the material of the respective hardmask portions exposed at the bottom of the deepened second trenches, thereby creating second via openings which expose the gate structures of the second type,
filling the second via openings and the deepened second trenches with an electrically conductive material, to thereby obtain the second via connections, and
planarizing the electrically conductive material and the second dielectric layer to thereby obtain the second conductive lines embedded in the planarized second dielectric layer.

7. The method according to claim 1, wherein the gate layer is a single layer of gate material so that the mask portions are formed directly on respective gate structures formed uniformly of the gate material.

8. The method according to claim 1, wherein the gate layer comprises a bottom layer formed of a first gate material and a top layer directly on the bottom layer and formed of a second gate material, so that the mask portions are formed directly on respective gate structures formed of a stack of a bottom gate portion of the first gate material and a top gate portion of the second gate material on top of the first gate portion.

9. The method according to claim 8, wherein the formation of the first via openings includes the removal of at least part of the top gate portions of the gate structures of the first type relative to the bottom gate portions.

10. The method according to claim 8, wherein the formation of the second via openings includes the removal of at least part of the hardmask portion on the gate structures of the second type without removing the top gate portions of the gate structures of the second type.

11. The method according to claim 1, wherein the lateral dimensions of the gate structures and the spacing between adjacent gate structures are between 5 and 50 nm.

12. The method according to claim 1, wherein the thickness of the conformal layer is between 1 and 5 nm.

13. The method according to claim 1, wherein the material of the hardmask portions is silicon nitride.

14. The method according to claim 1, wherein the conformal layer comprises at least a top layer formed of silicon carbonate.

15. The method according to any claim 8 wherein the second gate material is a metal.

16. A spin qubit quantum dot device comprising:
an array of alternately arranged gate structures of a first and second type arranged in a longitudinal direction on a planar surface,
first via connections to the gate structures of the first type, the first via connections being connected to respective first conductive lines running essentially parallel to the planar surface, and
second via connections to the gate structures of the second type, the second via connections being connected to respective second conductive lines running essentially parallel to the planar surface,
wherein the first and the second conductive lines are embedded in a layer of dielectric material, the layer comprising spacers on the sidewalls of the first conductive lines.

17. The device according to claim 16, wherein the lateral dimensions of the gate structures and the spacing between adjacent gate structures are between 5 and 50 nm.

18. The device according to claim 16, wherein the thickness of the spacers is between 1 and 5 nm.

19. The device according to claim 16, wherein the gate structures comprise a single type of material.

20. The device according to claim 16, wherein the gate structures comprise a bottom layer formed of a first gate material and a top layer formed of a second gate material, wherein the second gate material is a metal.
